(19) United States
(12) Patent Application Publication
(10) Pub. No.: US 2006/0225654 A1
(43) Pub. Date: Oct. 12, 2006

(54) Disposable plasma reactor materials and methods

(76) Inventor: Steven T. Fink, Mesa, AZ (US)

Correspondence Address: DLA PIPER RUDNICK GRAY CARY US LLP, P. O. BOX 9271, RESTON, VA, 20195, US

(21) Appl. No.: 11/091,775

(22) Filed: Mar. 29, 2005

(51) Int. Cl. C23F 1/00; C23C 16/00

(52) U.S. Cl. 118/723 R; 156/914; 156/345.47

(57) ABSTRACT

The present invention provides a disposable component for a plasma processing system, wherein the component includes a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof.

### CROSS-REFERENCE TO RELATED APPLICATIONS

This application is related to U.S. patent application Ser. No. 11/032,101, filed Jan. 11, 2005, entitled “Plasma Processing System and Baffle For Use In Plasma Processing System,” U.S. patent application Ser. No. 10/889,220, filed Jul. 13, 2004, entitled “Method and Apparatus For Delivering Process Gas to a Process Chamber,” U.S. patent application No. 10/705,224, filed Nov. 12, 2003, entitled “Method and Apparatus For Improved Baffle Plate,” the entire contents of each of which being incorporated herein by reference.

### FIELD OF THE INVENTION

The present invention relates to disposable materials and/or components for plasma reactors and methods of making and using same.

### BACKGROUND OF THE INVENTION

The fabrication of integrated circuits in the semiconductor industry typically employs plasma to create and assist surface chemistry within a plasma reactor to remove material from and deposit material to a substrate. Plasma is typically formed within the plasma reactor under vacuum conditions by heating electrons to energies sufficient to sustain ionizing collisions with a supplied process gas. Moreover, the heated electrons can have energy sufficient to sustain dissociative collisions and, therefore, a gas or gases under predetermined conditions (e.g. chamber pressure, gas flow rate, etc.) may be chosen to produce a population of charged species and/or chemically reactive species suitable to the particular process being performed within the chamber (e.g. etching processes where materials are removed from the substrate or deposition processes where materials are added to the substrate). Many surfaces and components of the plasma reactor, and particularly those in contact with the plasma, are subject to erosion or material deposition or both. The result is that periodic cleaning and/or replacement of component parts is necessary.

### SUMMARY OF THE INVENTION

One embodiment of the present invention provides a disposable component adapted for use in a plasma processing system, wherein the component includes a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof.

One embodiment of the present invention provides a plasma processing system including at least one plasma source and at least one disposable component. The disposable component includes a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof.

One embodiment of the present invention provides a method including contacting a plasma processing system with at least one disposable component which includes a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof.

One embodiment of the present invention provides a method including contacting, in a plasma processing system that includes at least one plasma source and at least one disposable component that includes a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof, a plasma with the component.

One embodiment of the present invention provides a method including from a plasma processing system that includes at least one plasma source and at least one disposable component that includes a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof, removing the component and disposing of the component.

### DESCRIPTION OF THE FIGURES

FIG. 1 shows a sectional view of an embodiment of a plasma chamber according to the present invention.

FIG. 2 shows a partial section view of an embodiment of an electrode plate assembly according to the present invention.

FIG. 3 shows a partial section view of an embodiment of another electrode plate assembly according to the present invention.

FIGS. 4A and 4B show partial section views of embodiments of focus/shield rings according to the present invention.

FIG. 5 shows a sectional view of an embodiment of a chamber liner according to the present invention.

FIG. 6 shows an embodiment of a baffle assembly according to the present invention.

FIG. 7 shows an embodiment of a bellows shield according to the present invention.

### DETAILED DESCRIPTION OF SEVERAL EMBODIMENTS

The present invention desirably provides a low-cost alternative to conventional plasma processing components and methods. Typically, parts in semiconductor and/or plasma processing systems are expensive to manufacture, clean and maintain. With the present invention, a plasma reactor user can significantly enhance instrument performance without driving up instrument cost. In contrast to conventional plasma components and methods, wherein regular maintenance, refurbishment and/or cleaning is required, the present invention allows the user to simply discard a used component and replace it with a new one. This is made possible at least in part by certain materials as plasma reactor components, the use of which for such applications has not been previously suggested. With the present invention, no cleaning or refurbishment of these component parts is necessary. When the particular plasma processing component requires maintenance, it is simply thrown away and replaced with a new one.

One embodiment of the present invention relates to the use of disposable materials in plasma processing systems. The term, “disposable component”, as used herein, means designed to be disposed of instead of maintained, e.g., when a conventional component would be cleaned. Nonlimiting examples of such disposable materials include refractory ceramic fiber, non-refractory ceramic fiber, alumina, alumina-silica and/or zirconia. The material may be in any form including a rigid material, flexible material, paper, cloth, felt, mat, screen, sheet, tape, blanket, fiber, woven fiber, or nonwoven fiber, or any combination of two or more thereof, and the like. The present inventor has found that plasma processing parts made from these disposable materials can be fabricated more easily and more cheaply than parts made from metallic parts, monolithic ceramic parts, or ceramic- or quartz-coated parts or other coated metallic parts.

In one embodiment, the disposable component includes 50% by weight or more of the non-refractory ceramic fiber, refractory ceramic fiber, alumina, alumina-silica, or zirconia, or any combination of two or more thereof. This includes 50, 55, 60, 65, 70, 75, 80, 85, 90, 95, 97, 99, and 100% by weight.

The present invention is suitable in many aspects of plasma reactors and processing systems. These include parts located in and/or around the process chamber(s) and the so-called “consumable” parts. These parts may be eroded by the plasma process or may have material deposited on their surfaces during the plasma process. These parts are common to various plasma processing systems and include, for example, focus rings, shield rings, baffles, baffle assemblies, pumping baffle plates, chamber liners, deposition shields, and the like. Conventionally, such parts often require regular cleaning, maintenance, or replacement. Fabricating or replacing these parts with the disposable materials of the present invention provides the user with significant advantages in terms of cost, down time, and turnaround rate.

The present invention is also suitable for use in other components of plasma processing systems that are not subject to plasma erosion and/or are not subject to material deposition, but which nevertheless require regular cleaning, maintenance, or replacement. These components are common in plasma processing systems and include the so-called “non-consumable” parts. Suitable examples of non-consumable parts include baffle plates, baffle plate assemblies, bellows assembly, bellows shields, and the like. Fabricating or replacing non-consumable parts using the disposable materials of the present invention provides the user with significant advantages in terms of cost, down time, and turnaround rate.

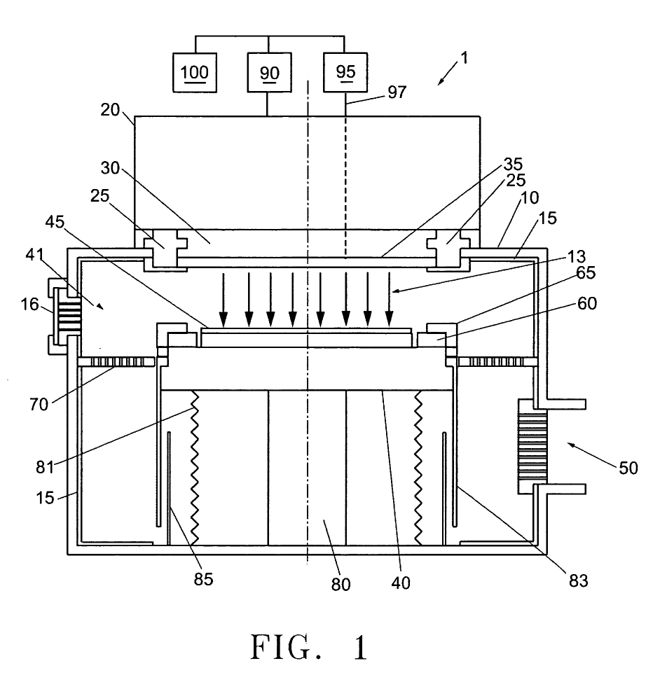

Referring now to FIG. 1, one embodiment of a plasma processing system 1 is depicted having a plasma processing chamber 10, an upper assembly 20, an electrode plate assembly 30, a chuck assembly 40 for supporting a substrate 45, and a pumping duct 50 coupled to a vacuum pump (not shown) for providing a reduced pressure atmosphere 41 in plasma processing chamber 10. Plasma processing chamber 10 can facilitate the formation of a plasma region 13 in the process space adjacent substrate 45. The plasma processing system 1 can be configured to process substrates of any size, including substrates of 100, 200, 250, 300, 350, 400, 450, 500 mm in diameter, and larger.

Chuck assembly 40 may be suitably coupled to one or more of a focus ring 60 and/or a shield ring 65. A baffle assembly 70 may extend around the periphery of the chuck assembly 40. The baffle assembly 70 is suitably used to help confine the plasma to a processing region 13 near or adjacent the substrate 45, as well as to affect the uniformity of fluid mechanical properties in the processing region 13 near or adjacent the substrate 45. The baffle assembly 70 may include one or more openings to permit the passage of process gases, reactants and/or reaction products to the vacuum pumping system. The baffle assembly 70 may be adapted to surround the chuck assembly 40 and, in many cases, the baffle assembly 70 is physically coupled to the chuck assembly 45 using fasteners.

The plasma process chamber 10 may suitably include a chamber liner 15 on a whole or a part of the interior surface thereof. The chamber liner 15 may be affixed to an interior portion of the process chamber 10 by one or more fasteners, hooks, retaining rings, retaining blocks, batten and panel devices, threaded fasteners, snaps, buttons, pins, slot and tab devices, clips, counter bored mating devices, magnetic devices, combinations thereof, and the like.

Plasma process chamber 10 may suitably include an optical viewport 16 to permit monitoring of optical emission from the processing plasma in plasma region 13.

Chuck assembly 40 may also include a vertical translational device 80 surrounded by a bellows 81 coupled to the chuck assembly 40 and the plasma processing chamber 10, and configured to seal the vertical translational device 80 from the reduced pressure atmosphere 41 in plasma processing chamber 10. The vertical transitional device 80 allows for the control and adjustment of the distance between the gas inject plate 35 and the substrate 45. An outer bellows shield 83 may be coupled to the chuck assembly 40 and configured to protect the bellows 81 from the processing plasma. An inner bellows shield 85 may also be coupled to the plasma processing chamber 10 to further protect the bellows 81 from the process plasma.

Substrate 45 may be transferred into and out of plasma processing chamber 10 through a slot valve (not shown) and chamber feed-through (not shown) via robotic substrate transfer system where it is received by substrate lift pins (not shown) housed within chuck assembly 40 and mechanically translated by devices housed therein. Once substrate 45 is received from substrate transfer system, it is lowered to and/or contacted with an upper surface of chuck assembly 40.

Substrate 45 can be affixed to the chuck assembly 40 via an electrostatic or mechanical clamping system. Chuck assembly 40 may also include a cooling system (not shown) having a recirculating coolant flow, thermal link, or other heat sink that receives heat from chuck assembly 40 and transfers heat to a heat exchanger system (not shown), or when substrate heating is desired, transfers heat from the heat exchanger system to the substrate 45. In addition, gas may be suitably delivered to the backside of substrate 45 via a backside gas system (not shown) to improve the gas-gap thermal conductance between substrate 45 and chuck assembly 40. Such a system can be utilized when temperature control of the substrate is required at elevated or reduced temperatures. In other embodiments, heating elements, such as resistive heating elements, or thermoelectric heaters/coolers can be included.

Chuck assembly 40 may include an electrode (not shown) through which RF power is coupled to the processing plasma in process space 13. For example, chuck assembly 40 can be electrically biased at an RF voltage via the transmission of RF power from an RF generator 90 through an impedance match network (not shown) to chuck assembly 40. The RF bias can serve to heat electrons to form and maintain plasma. In this configuration, the system can operate as a reactive ion etch (RIE) reactor, wherein the chamber and upper gas injection electrode serve as ground surfaces. A typical frequency for the RF bias can range from approximately 1 MHz to approximately 100 MHz or approximately 13.56 MHz. RF systems for plasma processing are well known to those skilled in the art.

In an alternate embodiment, upper assembly 20 can include a cover and/or an upper electrode impedance match network. The electrode plate assembly 30 may be suitably coupled to an RF source. In another alternate embodiment, the upper assembly 20 may include a cover coupled to the electrode plate assembly 30, wherein the electrode plate assembly 30 is maintained at an electrical potential equivalent to that of the plasma processing chamber 10. For example, the plasma processing chamber 10, the upper assembly 20, and the electrode plate assembly 30 can be electrically connected to ground potential. Alternatively, an insulator 25 may electrically isolate the electrode plate assembly from the walls of the process chamber 10.

In other embodiments, the processing plasma in process space 13 can be formed using a parallel plate, capacitively coupled plasma (CCP) source, an inductively coupled plasma (ICP) source, or any combination thereof, with or without magnet systems. The processing plasma in process space 13 can also be formed using electron cyclotron resonance (ECR) or a Helicon wave. In another embodiment, the processing plasma in process space 13 is formed from a propagating surface wave.

The plasma processing system may suitably include a gas supply system 95 in pneumatic communication with the plasma chamber 10 via one or more gas conduits 97 for supplying gas in a regulated manner to the form the plasma. Gas supply system 95 can supply one or more gases such as inert gases, reactive gases, reactants, CVD source gases, passivating gases, chlorine, HBr, HCl, octafluorocyclobutane, fluorocarbons, silanes, tungsten tetrachloride, or titanium tetrachloride, or the like.

The plasma processing system 1 may suitably include a main control system 100 to which the power and gas supply system and other systems may be connected. In one embodiment, the main control system 100 is a computer having a memory unit with both random access memory and read only memory, a central processing unit, hard disk, optionally a disk drive, all in electronic communication.

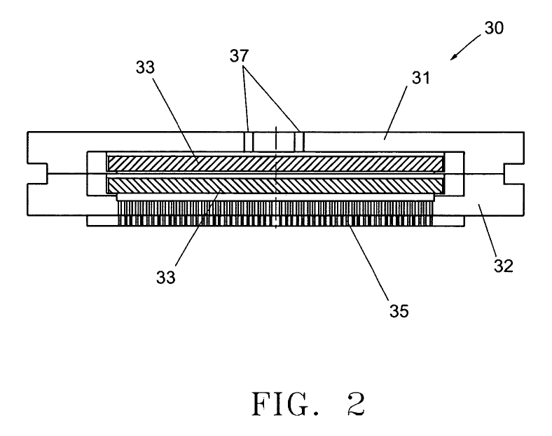

One embodiment of the invention is shown in FIG. 2, wherein a partial section view of an electrode plate assembly 30 in a capacitively coupled plasma (CCP) source is depicted. The electrode plate assembly 30 may include an upper electrode plate 31 sandwiched to a lower electrode plate 32. The electrode plate assembly 30 may also include one or more baffle plate assemblies 33. The function of the baffle plate assemblies 33 is to evenly disperse gas to the gas inject plate 35 from one or more gas inlet(s) 37 in the upper electrode plate 31. Other suitable configurations for the any one of the electrode assembly 30, upper and lower electrode plates 31 and 32, inlet(s) 37, baffle plate assembly 33, are described in U.S. Provisional application Ser. No. 60/486,548, filed Jul. 14, 2003, and 60/503,890, filed Sep. 22, 2003, and the U.S. Utility application claiming priority thereto, application Ser. No. 10/889,220, filed Jul. 13, 2004, entitled “Method and Apparatus for Delivering Process Gas to a Process Chamber”, the entire contents of each of which are hereby incorporated by reference.

Any one or all of the baffle plate assemblies 33 may be made from disposable material in accordance with the present invention. The baffle plate assembly 33 may be made from paper, mat, felt, or blanket materials, or any combination of two or more thereof. In view of allowing the passage of gas, reactants, and the like between the gas inlet(s) 37 and the gas inject plate 35, the baffle plate assembly 33 may be perforated, or it may be non-perforated but porous, or it may be perforated and porous. Non-perforated, non-porous baffle plate assemblies 33 are also contemplated within the scope of the invention. Where a plurality of baffle plate assemblies 33 are present, a combination of perforated and non-perforated baffle plate assemblies 33 may be suitably used. Any perforation may be suitably used, including any hole, slot, open polygon, open character of any language, or open shape, or any combination of two or more thereof, or the like.

The gas inject plate 35 may also be suitably made from disposable material in accordance with the present invention. The gas inject plate 35 may be made from paper, mat, felt, or blanket materials, or any combination of two or more thereof. In view of allowing the passage of gas, reactants, and the like between the gas inlet(s) 37 and the plasma region 13, the gas inject plate 35 may be perforated, or it may be non-perforated but porous, or it may be perforated and porous. One or more than one gas inject plate 35 may be used. Where a plurality of gas inject plates 35 are present, a combination of perforated and non-perforated gas inject plates 35 may be suitably used. Any perforation may be suitably used, including any hole, slot, open polygon, open character of any language, or open shape, or any combination of two or more thereof, or the like.

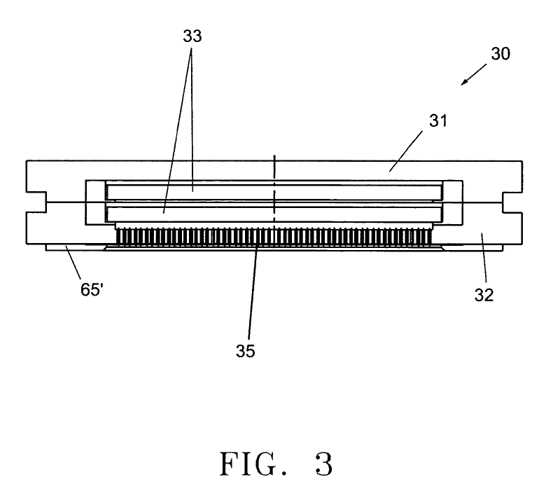

One embodiment is shown in FIG. 3, wherein a partial section view of an electrode plate assembly 30 in a capacitively coupled plasma (CCP) source is depicted, perforated paper is used for the gas inject plate 35. In this embodiment, an alternate shield ring 65′ is shown.

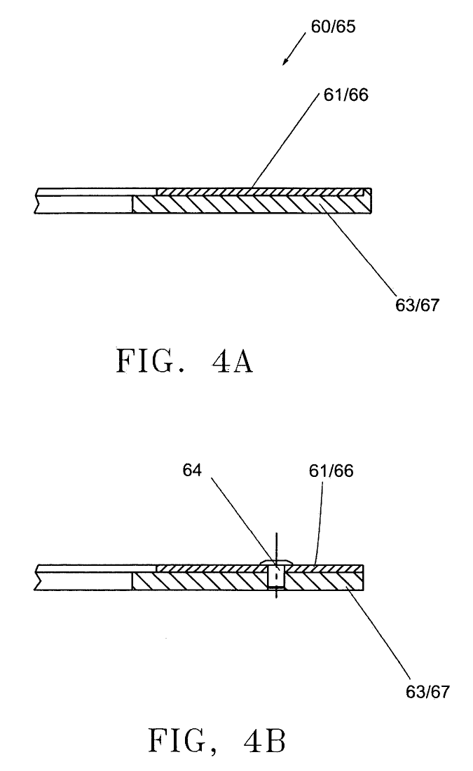

Any or all of the focus ring 60 or shield ring 65 surrounding the chuck assembly 40, or the alternate shield ring 65′ may be made from the disposable materials described herein, particularly alumina, alumina-silica, and/or zirconia mat, felt, or paper. Either or both of these rings may be retained in whole or in part by any appropriate retaining device or fastener to the chuck assembly 40. An alternative embodiment is shown in FIG. 4A as a partial section view of a multipart ring is shown. In this embodiment, a ring such as a focus ring 60 or shield ring 65 is formed of multiple parts in which a focus ring insert 61 or shield ring insert 66 is supported by a focus ring support 63 or shield ring support 67. In this embodiment, any of the focus ring insert 61, focus ring support 63, shield ring insert 66, and/or shield ring support 67 may be made from the disposable materials described herein. The inserts may be retained in or supported by the supports by one or more ways including counter-bored mating features, tab and slot devices, or held in place by one or more threaded fasteners or pins. Multipart focus rings and multipart shield rings may be used either alone or in combination.

In one embodiment, the focus ring insert 61 and/or shield ring insert 66 is made of paper, and the accompanying focus ring support 63 and/or shield ring support 67 is made of conventional material such as aluminum or aluminum honeycomb. In another embodiment, such as one in which a deposition process is used in the plasma processing system 1, felt, mat or blanket materials may be used instead of paper.

One embodiment in partial section view is shown in FIG. 4B, wherein a multipart ring such as shown in FIG. 4A is depicted, but wherein a button 64 is used to affix the ring insert 61 or 66 to the ring support 63 or 67. The button may be suitably made from a material such as ceramic or silicon. One or more than one buttons 64 may be used.

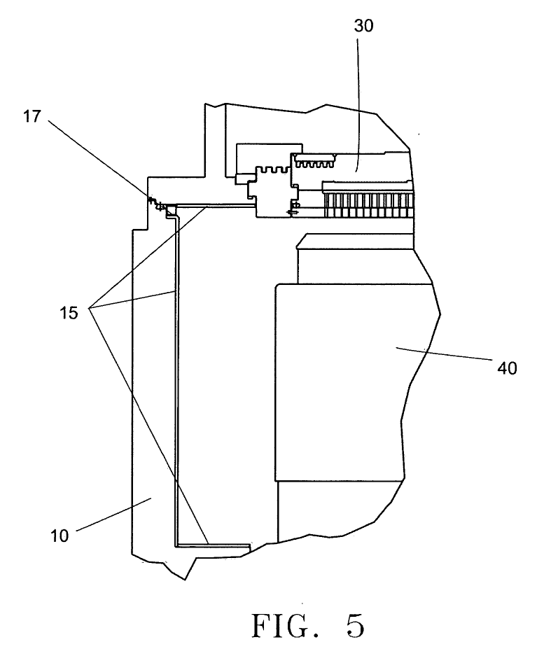

One embodiment is shown in FIG. 5, in which a portion of plasma processing system 1 is shown in partial section view. In this embodiment, chuck assembly 40, electrode assembly 30, and process chamber 10 are shown. Nonlimiting suitable locations for the chamber liner 15 are also shown, and one embodiment of a chamber liner retaining ring 17 is shown. The chamber liner 15 may be made from disposable material such as paper, felt, mat, or blanket, or any combination of two or more thereof, or the like. In the case of non-deposition plasma processes, the whole or part of the chamber liner 15 may be made from paper if desired. In the case of deposition plasma processes, the whole or part of the chamber liner 15 may be made from felt, mat or blanket materials instead of paper. The chamber liner 15 may be affixed to an interior portion of the process chamber 10 by one or more fasteners, hooks, retaining rings, retaining blocks, batten and panel devices, threaded fasteners, snaps, buttons, pins, slot and tab devices, clips, counter bored mating devices, or magnetic devices, or any combination of two or more thereof, or the like.

In accordance with another embodiment of the present invention, the chamber liner retaining ring 17 may also be made from disposable material if desired.

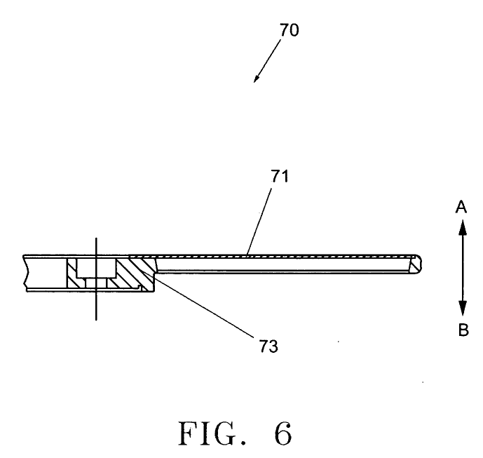

One embodiment of a baffle assembly 70 is shown in partial section view in FIG. 6. Here, the baffle assembly 70 is shown as a multipart plate. The multipart plate includes one or more baffle inserts 71 supported by or retained in a baffle carrier 73. Either or both of these may be made from disposable materials in accordance with the present invention. The baffle insert 71 may be made from paper, mat, felt, or blanket materials, or any combination of two or more thereof, or the like. In view of allowing the passage of gas, reactants, etc., between the plasma region 13 and the pumping duct 50 (e.g., shown as the A-B direction in FIG. 6), the baffle insert 71 may be perforated, or it may be non-perforated but porous, or it may be perforated and porous. Non-perforated, non-porous baffle inserts 71 are also contemplated within the scope of the invention. The baffle insert 71 may be suitably made from disposable paper, mat, felt, or blanket, or any combination of two or more thereof, or the like in accordance with the present invention. Where a plurality of baffle inserts 71 are present, a combination of perforated and non-perforated baffle inserts 71 may be suitably used about the baffle carrier 73. Any perforation may be suitably used, including any hole, slot, open polygon, open character of any language, or open shape, or any combination of two or more thereof, or the like.

Suitable multipart baffle assemblies 70 are described, for example, in U.S. patent application Ser. No. 11/032,101, filed Jan. 11, 2005, entitled “Plasma Processing System and Baffle Assembly for Use in Plasma Processing System,” the entire contents of which are hereby incorporated by reference. Any of the baffle components described therein may be suitably made from the disposable materials described herein. The baffle inserts 71 may be affixed to the baffle carrier 73 or they may simply be in contact with the baffle carrier 73. The baffle inserts 71 may be suitably affixed to the baffle carrier with one or more fasteners, hooks, retaining rings, retaining blocks, batten and panel devices, threaded fasteners, snaps, buttons, pins, slot and tab devices, clips, counter bored mating devices, or magnetic devices, or any combination of two or more thereof, or the like.

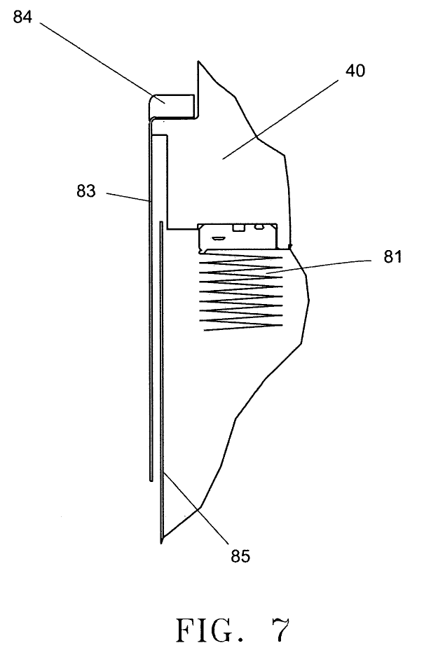

One embodiment is shown in partial section view in FIG. 7, wherein the chuck assembly 40, bellows assembly 81, outer bellows shield 83, outer bellows shield retaining ring 84, and inner bellows shield 85 are depicted. The bellows shield retaining ring 84 suitably affixes the outer bellows shield 83 to the chuck assembly 40, but any affixing device may be used. All or a portion of any of the outer bellows shield 83, outer bellows shield retaining ring 84, and/or inner bellows shield 85 may be made from disposable material in accordance with the present invention. In one embodiment, the outer bellows shield 83 is made from paper such as alumina-silica and is affixed to the chuck assembly using a retaining ring 84 or any other suitable device such as one or more fasteners, hooks, retaining blocks, batten and panel devices, threaded fasteners, snaps, buttons, pins, slot and tab devices, clips, counter bored mating devices, or magnetic devices, or any combination of two or more thereof, or the like.

In another embodiment, all or a portion of the inner bellows shield 85 may be suitably made from disposable material.

Other embodiments of the present invention include methods for changing, replacing, and/or disposing one or more of the disposable components described herein. One nonlimiting example includes a method for replacing one or more disposable baffle assemblies 70 surrounding the chuck assembly 40 in a plasma processing system 1. The method includes removing a baffle assembly 70 from the plasma processing system 1. Removing the first baffle assembly 70 may, for example, include venting the plasma processing system 1 to atmospheric conditions, opening the plasma processing chamber 10 to access the interior, decoupling the baffle assembly 70 from the chuck assembly 40. Decoupling the baffle assembly 70 from the chuck assembly 40 may, for example, include lifting the baffle assembly 70 away from the chuck assembly 40, or removing one or more fasteners adapted to fasten the baffle assembly 70 to the chuck assembly 40 and then lifting the baffle assembly 70 away from the chuck assembly 40. The used baffle assembly 70 is then discarded. The method may be suitably adapted to any one or all of the disposable components within the scope of the invention.

In the above-described method, a second, unused and/or unrefurbished disposable baffle assembly 70 may be installed in the plasma processing system 1 by coupling the second baffle assembly 70 to the chuck assembly 40, the plasma processing chamber 10 may then be closed, and then evacuated to a suitable reduced operating pressure with the vacuum pump. As before, the method may be suitably adapted to any one or all of the disposable components and to any plasma processing system within the scope of the invention.

In an alternative embodiment, the baffle assembly 70 may be removed, one or more of the baffle inserts 71 may be replaced and discarded, and the baffle assembly 70 may be reinstalled.

The method set forth above may be employed with any of the components in the processing chamber 10.

Another embodiment provides a plasma reactor or plasma processing system 1, which includes one or more disposable components of the present invention.

Another embodiment provides a method for using a plasma reactor or plasma processing system 1, which includes contacting a portion of a plasma reactor or plasma processing system 1 with a plasma, wherein the plasma reactor or plasma processing system 1 includes one or more disposable components of the present invention.

Another embodiment provides a method for modifying the surface of a substrate 45, which includes contacting a substrate 45 surface with a plasma generated in a plasma reactor or plasma processing system 1 having one or more disposable components in accordance with the present invention.

Particularly suitable disposable materials include those made by Zircar Zirconia, Inc., Zircar Refractory Composites, Inc., and Zircar Ceramics, Inc., all of Florida, N.Y. These include rigid material, flexible material, paper, cloth, felt, mat, screen, sheet, tape, blanket, fiber, woven fiber, or nonwoven fiber, or any combination of two or more thereof, or the like, machined, woven, drawn or otherwise made from refractory ceramic fibers, non-refractory ceramic fibers, alumina, alumina-silica, zirconia, or ceramics, or the like such as Type ZYF Zirconia Felt C-AB, Type ZYK-15 Zirconia Knit Cloth C-C, Type ZYW Zirconia Woven Cloth C-DE, or Type ZYBF Zirconia Bulk Fiber, or the like made by Zircar Zirconia, Inc.; ASPA-1 Paper, ASPA-2 Paper, ASPA-880 Paper, ASPA-970 Paper, RS CLOTH, RS-DA Sheet, RS-DD Sheet, RS-DM Sheet, RS-DR Sheet, RSBL-SOL Blanket, RSPA-SOL2 Paper, RSPA-SOL3 Paper, RSPA-SOL4 Paper, RS-TAPE, SB-2000 Blanket, SIL-1 Cloth, SIL-2 Cloth, or SIL-3 Cloth, or the like made by Zircar Refractory Composites, Inc.; or Alumina Papers Type APA, Alumina Mat, Alumina Blanket Type AB & Type MB, Alumina-Silica Blanket Type ASB-2300 & ASB-2600, Alumina-Silica Textile Type AS-1260, or Non-RCF Blanket Type Z-MAG-B, or the like made by Zircar Ceramics, Inc. Combinations of two or more materials are possible.

The present invention may be suitably applied to any plasma processing system. One example of a plasma processing system includes a semiconductor plasma processing system. Other plasma processing systems suitable for application of the present invention include those for plasma surface treatment, plasma etching, plasma thin film deposition (e.g., synthetic diamond film and high-temperature superconducting film), synthesis of materials, destructive plasma chemistry (e.g., toxic waste treatment, destruction of chemical warfare agents), or plasma chemistry (produce active species to etch, coat, clean and otherwise modify materials), or the like. The present invention is not limited to low pressure plasma reactors, however, and the materials and methods described herein may be suitably applied in any plasma application as desired. Other examples of plasma systems suitable for the present invention include those for isotope enrichment, meat pasteurization, water treatment systems, electron scrubbing of flue gases in coal or solid waste burning, sterilization of medical instruments, production of fullerenes, plasma polymerization, surface treatment of fabrics (e.g., for improved wettability, wickability, printability of polymer fabrics and wool), metal recovery, primary extraction, scrap melting, waste handling in pulp, paper, and cement industries, and the like.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention. In addition, the entire contents of each of the patents, applications, and articles cited herein is hereby incorporated by reference, the same as if set forth at length.

What is claimed is:

1. A disposable component adapted for use in a plasma processing system, wherein said component comprises a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof.

2. The disposable component of claim 1, which comprises at least 50% by weight or more of the non-refractory ceramic fiber, refractory ceramic fiber, alumina, alumina-silica, or zirconia, or any combination of two or more thereof.

3. The disposable component of claim 1, which comprises at least 75% by weight of the non-refractory ceramic fiber, refractory ceramic fiber, alumina, alumina-silica, or zirconia, or any combination of two or more thereof.

4. The disposable component of claim 1, which consists essentially of the non-refractory ceramic fiber, refractory ceramic fiber, alumina, alumina-silica, or zirconia, or any combination of two or more thereof.

5. The disposable component of claim 1, which is a focus ring, focus ring insert, shield ring, shield ring insert, baffle, baffle insert, baffle assembly, baffle plate, chamber liner, deposition shield, bellows assembly, or bellows shield, or any combination of two or more thereof.

6. The disposable component of claim 1, which is in the form of a paper, cloth, felt, mat, or blanket, or any combination of two or more thereof.

7. The disposable component of claim 1, which is gas-permeable or gas-impermeable.

8. The disposable component of claim 1, comprising at least one gas-permeable part and at least one gas-impermeable part.

9. A plasma processing system, comprising:
at least one plasma source; and
at least one disposable component comprising at least one non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof.

10. The system of claim 9, wherein said disposable component comprises at least 50% by weight or more of the non-refractory ceramic fiber, refractory ceramic fiber, alumina, alumina-silica, or zirconia, or any combination of two or more thereof.

11. The system of claim 9, wherein said disposable component is a focus ring, focus ring insert, shield ring, shield ring insert, baffle, baffle insert, baffle assembly, baffle plate, chamber liner, deposition shield, bellows assembly, or bellows shield, or any combination of two or more thereof.

12. A method, comprising:
contacting a plasma processing system with at least one disposable component comprising at least one non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof.

13. The method of claim 12, further comprising removing and disposing of said component.

14. The method of claim 12, wherein said disposable component comprises at least 50% by weight or more of the non-refractory ceramic fiber, refractory ceramic fiber, alumina, alumina-silica, or zirconia, or any combination of two or more thereof.

15. The method of claim 12, wherein said disposable component is a focus ring, focus ring insert, shield ring, shield ring insert, baffle, baffle insert, baffle assembly, baffle plate, chamber liner, deposition shield, bellows assembly, or bellows shield, or any combination of two or more thereof.

16. A method, comprising:
contacting, in a plasma processing system comprising at least one plasma source and at least one disposable component comprising a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof, a plasma with said component.

17. The method of claim 16, wherein said disposable component comprises at least 50% by weight or more of the non-refractory ceramic fiber, refractory ceramic fiber, alumina, alumina-silica, or zirconia, or any combination of two or more thereof.

18. The method of claim 16, wherein said disposable component is a focus ring, focus ring insert, shield ring, shield ring insert, baffle, baffle insert, baffle assembly, baffle plate, chamber liner, deposition shield, bellows assembly, or bellows shield, or any combination of two or more thereof.

19. A method, comprising:
from a plasma processing system comprising at least one plasma source and at least one disposable component comprising a non-refractory ceramic fiber, refractory ceramic fiber, alumina, alumina-silica, or zirconia, or any combination of two or more thereof in the form of a rigid material, flexible material, paper, cloth, felt, mat, screen, sheet, tape, blanket, fiber, woven fiber, or nonwoven fiber, or any combination of two or more thereof,
removing said component; and
disposing of said component.

20. The method of claim 19, further comprising, after said removing, contacting said system with at least one unused disposable component comprising a non-refractory ceramic fiber, refractory ceramic fiber, alumina, alumina-silica, or zirconia, or any combination of two or more thereof.
